(19) United States
(12) Patent Application Publication
(10) Pub. No.: US 2014/0182916 A1
(43) Pub. Date: Jul. 3, 2014

(54) CIRCUIT BOARD AND METHOD OF MANUFACTURING THE SAME

(71) Applicant: SAMSUNG ELECTRO-MECHANICS CO., LTD., Suwon (KR)

(72) Inventors: Yee Na SHIN, Suwon (KR); Seung Eun LEE, Sungnam (KR); Yul Kyo CHUNG, Yongin (KR); Doo Hwan LEE, Daejeon (KR)

(73) Assignee: SAMSUNG ELECTRO-MECHANICS CO., LTD., Suwon (KR)

(21) Appl. No.: 14/064,951

(22) Filed: Oct. 28, 2013

(30) Foreign Application Priority Data
Dec. 31, 2012 (KR) 10-2012-0157883

(51) Int. Cl. H05K 1/11; H05K 3/00

(52) U.S. Cl. CPC H05K 1/115; H05K 3/0094
USPC 174/262; 29/837

(57) ABSTRACT

The present invention relates to a circuit board, which can miniaturize a conductor pattern formed around a via and improve current pass characteristics of the via at the same time by including a via passing through an insulating layer to be in contact with an upper conductor pattern and a lower conductor pattern and having a bent portion whose cross-sectional area or diameter changes discontinuously.

### CROSS-REFERENCE TO RELATED APPLICATIONS

Claim and incorporate by reference domestic priority application and foreign priority application as follows:

### “CROSS REFERENCE TO RELATED APPLICATION

This application claims the benefit under 35 U.S.C. Section 119 of Korean Patent Application Serial No. 10-2012-0157883, entitled filed Dec. 31, 2012, which is hereby incorporated by reference in its entirety into this application.”

### BACKGROUND OF THE INVENTION

1. Field of the Invention

The present invention relates to a circuit board and a method of manufacturing the same.

2. Description of the Related Art

With the tendency for miniaturization of conductor patterns, the line width and pitch of the conductor patterns, which are respectively in contact with an upper surface and a lower surface of a via, are also continuously reduced.

However, as disclosed in Patent Document 1 etc., the via passing through an insulating layer generally has a wide-upper and narrow-lower shape.

Therefore, in order to miniaturize the conductor pattern formed on the surface including the upper surface of the via, the diameter of the upper surface of the via should be reduced. In order to achieve this, the diameter of the lower surface of the via also should be reduced.

However, the smaller the lower surface of the via is, the smaller the contact area between the conductor pattern formed under the insulating layer and the lower surface of the via is. Thus, there is a problem that reductions in reliability and signal transmission capability are caused by process variation.

Meanwhile, as disclosed in Patent Document 1 etc., techniques related to electronic component embedded circuit boards, which implement high performance as well as miniaturization and slimming of the circuit board by forming the multilayer circuit board and embedding an active device such as IC and a passive device such as an inductor or a capacitor in the circuit board, have been developed.

In the electronic component embedded circuit board, in order to efficiently utilize performance of the electronic component, a via, a circuit pattern, etc., which electrically connect between the internal electronic component and the outside, should perform a sufficient signal transmission function.

However, as described above, when reducing the diameter of the via for miniaturization of the circuit pattern, the entire volume of the via is also remarkably reduced and consequently current transmission performance of the via is reduced. Thus, there is a problem that the performance of the electronic component can't be sufficiently utilized when the via is connected to the electronic component of a high speed signal processing device or a high performance processor.

### RELATED ART DOCUMENT

### Patent Document

Patent Document 1: U.S. Patent Laid-open Publication No. 2011-0019383

### SUMMARY OF THE INVENTION

The present invention has been invented in order to overcome the above-described problems and it is, therefore, an object of the present invention to provide a technique that can improve reliability and connectivity of a via and miniaturize a conductor pattern connected to the via.

In accordance with one aspect of the present invention to achieve the object, there is provided a circuit board including: an insulating layer; an upper conductor pattern and a lower conductor pattern respectively provided on an upper surface and a lower surface of the insulating layer; and a via passing through the insulating layer to be in contact with the upper conductor pattern and the lower conductor pattern and having a bent portion whose cross-sectional area or diameter changes discontinuously.

At this time, the via may include a first body in contact with the lower conductor pattern; and a second body in contact with the upper conductor pattern and having a smaller volume than the first body, wherein the first body and the second body may be formed integrally.

Further, the bent portion may be formed on the boundary between the first body and the second body.

Further, the insulating layer may include a first insulating portion in which the first body is formed; and a second insulating portion which is formed on the first insulating portion and in which the second body is formed.

Here, it is preferred that the thickness of the second insulating portion is less than 0.9 times the thickness of the first insulating portion.

Further, the second insulating portion may have a lower laser absorption rate than the first insulating portion.

Further, the second insulating portion may have a higher chemical resistance to a desmear process solution than the first insulating portion.

At this time, the desmear process solution may include a sodium hydroxide solution or a permanganate solution.

Further, the first insulating portion may include PPG or ABF, and the second insulating portion may include at least one material selected from the group consisting of bisphenol A, phenolic novolac resin, silica, and TiO₄.

Further, a minimum value of the cross-sectional diameter of the second body may be smaller than the diameter of an upper surface of the via and larger than the diameter of a lower surface of the via.

Further, the diameter or cross-sectional area of the first body and the second body may increase from the lower conductor pattern side to the upper conductor pattern side.

At this time, an acute angle between a lower surface of the first insulating portion and a side surface of the first body may be larger than that between a lower surface of the second insulating portion and a side surface of the second body.

Further, the diameter or cross-sectional area of the via may be maximum in the bent portion.

In accordance with another aspect of the present invention to achieve the object, there is provided a circuit board including: a first insulating layer having a cavity; an electronic component at least partially inserted in the cavity and having an external electrode; a second insulating layer provided on the first insulating layer to cover the electronic component; a conductor pattern provided on an upper surface of the second insulating layer; and a via passing through the second insulating layer to be in contact with the conductor pattern and the external electrode and having a bent portion whose cross-sectional area or diameter changes discontinuously.

At this time, the via may have a first body in contact with the external electrode; and a second body in contact with the conductor pattern and having a smaller volume than the first body, wherein the first body and the second body may be formed integrally.

Further, the bent portion may be formed on the boundary between the first body and the second body.

Further, the diameter or cross-sectional area of the via may be maximum in the bent portion.

Further, the second insulating layer may include a first insulating portion in which the first body is formed; and a second insulating portion which is formed on the first insulating portion and in which the second body is formed.

Here, it is preferred that the thickness of the second insulating portion is less than 0.9 times the thickness of the first insulating portion.

Further, the second insulating portion may have a lower laser absorption rate and a higher chemical resistance to a desmear process solution than the first insulating portion.

Further, the second insulating layers may be formed on an upper surface and a lower surface of the first insulating layer, and the conductor patterns may be formed on and under the first insulating layer in plural number.

Further, the external electrodes may be formed on an upper surface and a lower surface of the electronic component in plural number, and the vias may be formed on and under the electronic component in plural number to be in contact with the conductor pattern and the external electrode, respectively.

In accordance with another aspect of the present invention to achieve the object, there is provided a method of manufacturing a circuit board, including the steps of: forming a via hole in an insulating layer having a lower conductor pattern on a lower surface to expose the lower conductor pattern; forming a via by providing a conductive material in the via hole; and forming an upper conductor pattern in contact with an upper surface of the via, wherein the via may be formed to have a bent portion whose cross-sectional area or diameter changes discontinuously.

At this time, the insulating layer may include a first insulating portion in contact with the lower conductor pattern and a second insulating portion in contact with the upper conductor pattern, and the thickness of the second insulating portion may be less than 0.9 times the thickness of the first insulating portion.

Further, the insulating layer may include a first insulating portion in contact with the lower conductor pattern and a second insulating portion in contact with the upper conductor pattern, the step of forming the via hole may include a process of irradiating laser to the lower conductor pattern from above the second insulating portion, and the second insulating portion may have a lower laser absorption rate than the first insulating portion.

Further, the insulating layer may include a first insulating portion in contact with the lower conductor pattern and a second insulating portion in contact with the upper conductor pattern, the step of forming the via hole may include a process of irradiating laser to the lower conductor pattern from above the second insulating portion and a process of removing a portion of the second insulating portion and a portion of the first insulating portion using a desmear process solution, and the second insulating portion may have a higher chemical resistance to the desmear process solution than the first insulating portion.

At this time, the first insulating portion may include PPG or ABF, and the second insulating portion may include at least one material selected from the group consisting of bisphenol A, phenolic novolac resin, silica, and TiO₄.

In accordance with another aspect of the present invention to achieve the object, there is provided a method of manufacturing a circuit board, including the steps of: inserting at least a portion of an electronic component having an external electrode in a cavity provided in a first insulating layer; forming a second insulating layer on the first insulating layer to cover the electronic component; forming a via hole through the second insulating layer to expose the external electrode; forming a via by providing a conductive material in the via hole; and forming a conductor pattern in contact with an upper surface of the via, wherein the via may be formed to have a bent portion whose cross-sectional area or diameter changes discontinuously.

At this time, the second insulating layer may have a first insulating portion in contact with the external electrode and a second insulating portion in contact with the conductor pattern, and the second insulating portion may have a lower laser absorption rate and a higher chemical resistance to a desmear process solution than the first insulating portion.

Further, an inner layer pattern may be further provided on a surface of the first insulating layer, the first insulating portion may also cover the inner layer pattern, and in the step of forming the via hole, a via hole may be further formed to expose the inner layer pattern by passing through the second insulating portion and the first insulating portion.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a view schematically showing a circuit board in accordance with an embodiment of the present invention;

FIG. 2 is a view schematically showing a via provided in the circuit board in accordance with an embodiment of the present invention;

FIG. 3 is a view schematically showing a circuit board in accordance with an embodiment of the present invention;

FIGS. 4a to 4d are process cross-sectional views schematically showing a method of manufacturing a circuit board in accordance with an embodiment of the present invention, wherein FIG. 4a is a view schematically showing the state in which a first insulating portion is provided, FIG. 4b is a view schematically showing the state in which a second insulating portion is formed, FIG. 4c is a view schematically showing the state in which a via hole is formed, and FIG. 4d is a view schematically showing the state in which a via is formed;

FIG. 5 is a view schematically showing a circuit board in accordance with another embodiment of the present invention; and

FIGS. 6a to 6g are process cross-sectional views schematically showing a method of manufacturing a circuit board in accordance with another embodiment of the present invention, wherein FIG. 6a is a view schematically showing the state in which a first insulating layer having a cavity is provided, FIG. 6b is a view schematically showing the state in which an electronic component is inserted in the cavity, FIG. 6c is a view schematically showing the state in which a first insulating portion is formed, FIG. 6d is a view schematically showing the state in which a second insulating portion is formed, FIG. 6e is a view schematically showing the state in which a second insulating layer including a first insulating portion and a second insulating portion is formed under the first insulating layer, FIG. 6f is a view schematically showing the state in which a via hole is formed, and FIG. 6g is a view schematically showing the state in which a via and a conductor pattern are formed.

### DETAILED DESCRIPTION OF THE PREFERABLE EMBODIMENTS

Advantages and features of the present invention and methods of accomplishing the same will be apparent by referring to embodiments described below in detail in connection with the accompanying drawings. However, the present invention is not limited to the embodiments disclosed below and may be implemented in various different forms. The embodiments are provided only for completing the disclosure of the present invention and for fully representing the scope of the present invention to those skilled in the art. Like reference numerals refer to like elements throughout the specification.

Terms used herein are provided to explain embodiments, not limiting the present invention. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step, operation and/or device.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “in one embodiment” herein do not necessarily all refer to the same embodiment.

Hereinafter, configurations and operational effects of the present invention will be described in detail with reference to the accompanying drawings.

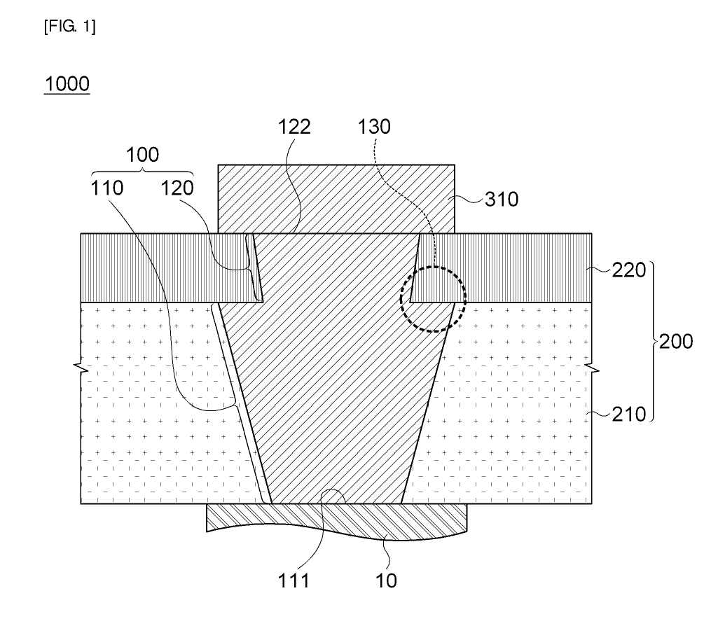

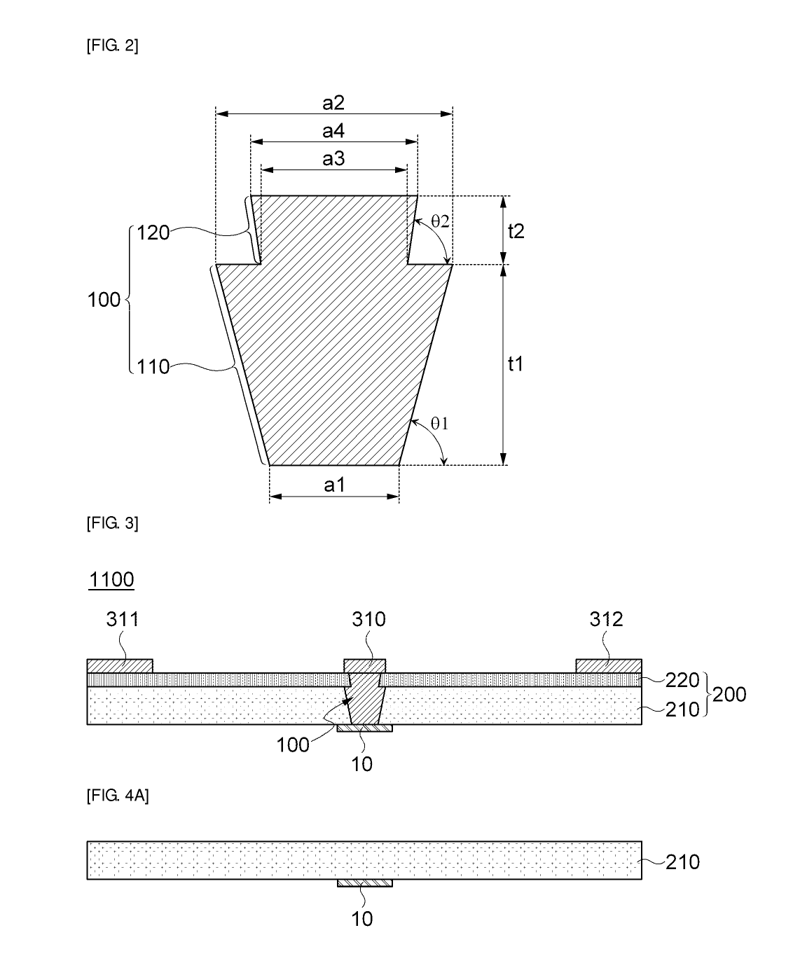

FIG. 1 is a view schematically showing a circuit board 1000 in accordance with an embodiment of the present invention, and FIG. 2 is a view schematically showing a via 100 provided in the circuit board 1000 in accordance with an embodiment of the present invention.

Referring to FIGS. 1 and 2, a circuit board 1000 in accordance with an embodiment of the present invention may include an insulating layer 200, an upper conductor pattern 310, a lower conductor pattern 10, and a via 100. The via 100 may have a bent portion 130 whose cross-sectional area or diameter changes discontinuously.

That is, it will be understood that the bent portion 130 is a portion having a discontinuous change that the cross-sectional area or diameter is constant or increased or reduced at a predetermined rate and then suddenly increased or reduced.

For example, the via 100 may be divided into a first body 110 and a second body 120 based on the bent portion 130. In other words, the bent portion 130 may be formed on the boundary between the first body 110 and the second body 120.

On the other hand, as shown, the diameter or cross-sectional area of the via 100 may be a maximum value a2 in the bent portion 130.

First, the first body 110 may mean a region in contact with the lower conductor pattern 10.

Next, the second body 120 may be in contact with the upper conductor pattern 310 and have a smaller volume than the first body 110.

Here, the first body 110 and the second body 120 are divided just for convenience of explanation and constitute the via 100 not by being separated from each other but by being formed integrally.

Meanwhile, the diameter or cross-sectional area of the first body 110 and the second body 120 may increase from the lower conductor pattern 10 side to the upper conductor pattern 310 side.

That is, each of the first body 110 and the second body 120 may have a wide-upper and narrow-lower shape like the typical via 100.

And, the second body 120 may be shorter than the first body 110.

Further, a minimum value a3 of the cross-sectional diameter of the second body 120 may be smaller than the diameter a4 of an upper surface 122 of the via and larger than a diameter al of a lower surface 111 of the via.

Further, the volume of the first body 110 may be larger than that of the second body 120.

To sum up these characteristics, the via 100 included in the circuit board 1000 in accordance with an embodiment of the present invention may substantially have a shovel or spade shape.

Accordingly, the diameter or cross-sectional area of the upper surface 122 of the via in contact with the upper conductor pattern 310 can be reduced than before. That is, compared to the conventional via whose diameter increases upward, since the diameter of the via 100 included in the circuit board 1000 in accordance with an embodiment of the present invention increases, decreases in the bent portion 130, and increases again, when the diameter or cross-sectional area of the lower surface and the height of the vias are equal, the diameter of the upper surface of the via 100 in accordance with the present invention can be reduced than the conventional via.

Consequently, a pattern width and a pattern pitch of the upper conductor pattern 310 can be reduced than before.

Further, since it is possible to maintain the diameter or cross-sectional area of the lower surface 111 of the via at a level similar to the prior art while reducing the diameter or cross-sectional area of the upper surface 122 of the via than the prior art, it is possible to improve reliability of connection between the via 100 and the lower conductor pattern 10 and current or signal transmission capability.

Continuously, referring to FIGS. 1 and 2, the insulating layer 200 may include a first insulating portion 210 and a second insulating portion 220. Here, the first body 110 may be positioned in the first insulating portion 210, and the second body 120 may be positioned in the second insulating portion 220 formed on the first insulating portion 210.

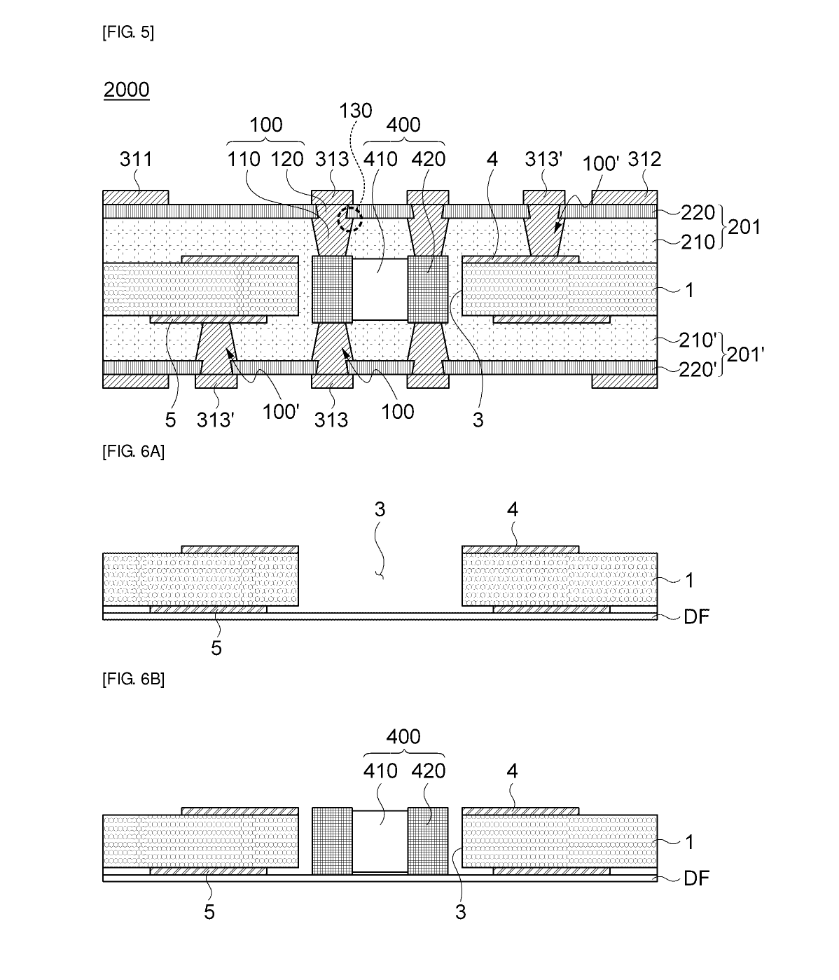

Generally, the via is formed by irradiating light such as laser to the insulating layer to process a via hole (refer to 340 of FIG. 4c) and providing a conductive material inside the via hole by a squeezing method, a plating method, etc.

In the circuit board 1000 in accordance with an embodiment of the present invention, it is possible to form the via 100 in the similar manner to the prior art.

That is, the via hole is processed by irradiating laser or light after forming the first insulating portion 210 and the second insulating portion 220 of the insulating layer 200.

Here, the first insulating portion 210 and the second insulating portion 220 may be made of materials having different laser absorption rates. Particularly, the second insulating portion 220 may be made of a material having a lower laser absorption rate than the first insulating portion 210.

Accordingly, even through laser is irradiated to the insulating layer 200 for the same time, the diameter or cross-sectional area of the via hole in the second insulating portion 220 may be smaller than that of the via hole in the first insulating portion 210.

Particularly, the diameter or cross-sectional area of the via hole is suddenly changed based on the boundary between the first insulating portion 210 and the second insulating portion 220. Accordingly, when forming the via 100 using the via hole formed over the first insulating portion 210 and the second insulating portion 220, the via 100 having the integrally connected first and second bodies 110 and 120 can be formed.

Meanwhile, when the first insulating portion 210 and the second insulating portion 220 are made of a photoreactive resin etc, the via hole may be formed by performing a desmear process after irradiating an ultraviolet ray etc., not laser. Here, a desmear process solution used in the desmear process may be a sodium hydroxide solution or a permanganate solution. It is possible to miniaturize the via hole formed in the second insulating portion 220 than the via hole formed in the first insulating portion 210 by forming the second insulating portion 220 with a material having a relatively high chemical resistance to the desmear process solution.

At this time, the first insulating portion 210 may be made of a material including PPG or ABF and the second insulating portion 220 may include at least one material selected from the group consisting of bisphenol A, phenolic novolac resin, silica, and TiO₄ to form the via 100 consisting of the first body 110 and the second body 120.

Meanwhile, an acute angle between a line extending from the lower surface 111 of the via and a side surface of the first body 110 may be defined as θ1. Further, an acute angle between a line parallel to the line extending from the lower surface 111 of the via and passing one point of a side surface of the second body 120 and the side surface of the second body 120 may be defined as θ2.

Further, an acute angle between a lower surface of the first insulating portion 210 and the side surface of the first body 110 may be defined as θ1, and an acute angle between a lower surface of the second insulating portion 220 and the side surface of the second body 120 may be defined as θ2.

One of the major purposes of the present invention is to reduce the diameter or cross-sectional area of the upper surface 122 of the via than the prior art while minimizing a reduction in the diameter or cross-sectional area of the lower surface 111 of the via, and this purpose can be achieved by the via 100 formed by integrally connecting the first body 110 and the second body 120 as described above.

Here, when θ2 is larger than θ1, the principle of achieving the purpose of the present invention can be more easily implemented.

Further, the smaller the minimum value a3 of the cross-sectional diameter of the second body 120 and the lower the height of the second body 120, the more easily the principle of achieving the purpose of the present invention is implemented.

However, there are difficult aspects to maximize all of these conditions. For example, when the minimum value a3 of the cross-sectional diameter of the second body 120 is too small, it is difficult to sufficiently fill a conductive material in an upper portion of the first body 110. Therefore, it is preferred that the minimum value a3 of the cross-sectional diameter of the second body 120 is smaller than the diameter a4 of the upper surface 122 of the via and larger than the diameter a1 of the lower surface 111 of the via.

Further, when the height of the second body 120 is higher than the height of the first body 110, since the effect of reduction of the diameter a4 of the upper surface 122 of the via is reduced, it is preferred that the height of the second body 120 is less than 0.9 times the height of the first body 110.

Particularly, considering that the first body 110 is positioned in the first insulating portion 210 and the second body 120 is positioned in the second insulating portion 220, it is preferred that the thickness of the second insulating portion 220 is less than 0.9 times the thickness of the first insulating portion 210.

Further, considering that the efficiency of filling a conductive material in the first body 110 is reduced according to a reduction of θ2 and an increase in the height of the second body 120, it is preferred that θ2 is larger than θ1.

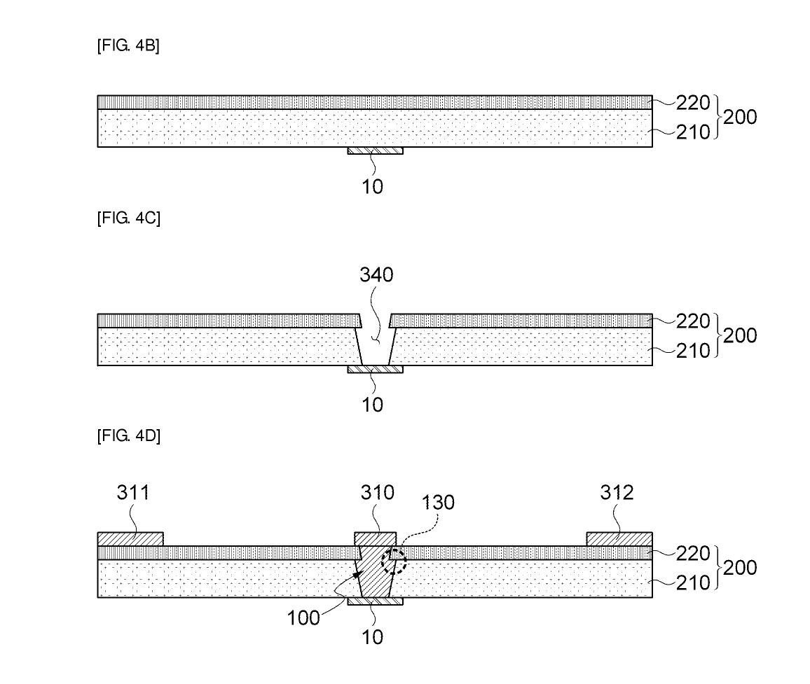

FIG. 3 is a view schematically showing a circuit board 1100 in accordance with an embodiment of the present invention.

Referring to FIG. 3, it will be understood that other conductor patterns 311 and 312 in addition to the upper conductor pattern 310 connected to the via 100 can be formed on the insulating layer 200.

FIGS. 4a to 4d are process cross-sectional views schematically showing a method of manufacturing a circuit board 1100 in accordance with an embodiment of the present invention.

First, referring to FIG. 4a, a lower conductor pattern 10 is formed on a lower surface of a first insulating portion 210.

Next, as shown in FIG. 4b, a second insulating portion 220 is formed on an upper surface of the first insulating portion 210.

Here, the first insulating portion 210 and the second insulating portion 220 may be sequentially formed or provided in a state of being coupled with each other.

Next, referring to FIG. 4c, a via hole 340 is processed by irradiating laser to the first insulating portion 210 from above the second insulating portion 220.

At this time, the second insulating portion 220 may have a lower laser absorption rate than the first insulating portion 210.

Accordingly, the via hole 340 substantially having a shovel shape can be formed as shown.

Meanwhile, as described above, the via hole 340 may be processed by performing a desmear process after irradiating light.

Next, referring to FIG. 4d, a via 100 is formed by providing a conductive material in the via hole 340 formed in the previous step. Further, an upper conductor pattern 310 is formed to be in contact with an upper surface 122 of the via. At this time, other conductor patterns 311 and 312 may be formed when necessary.

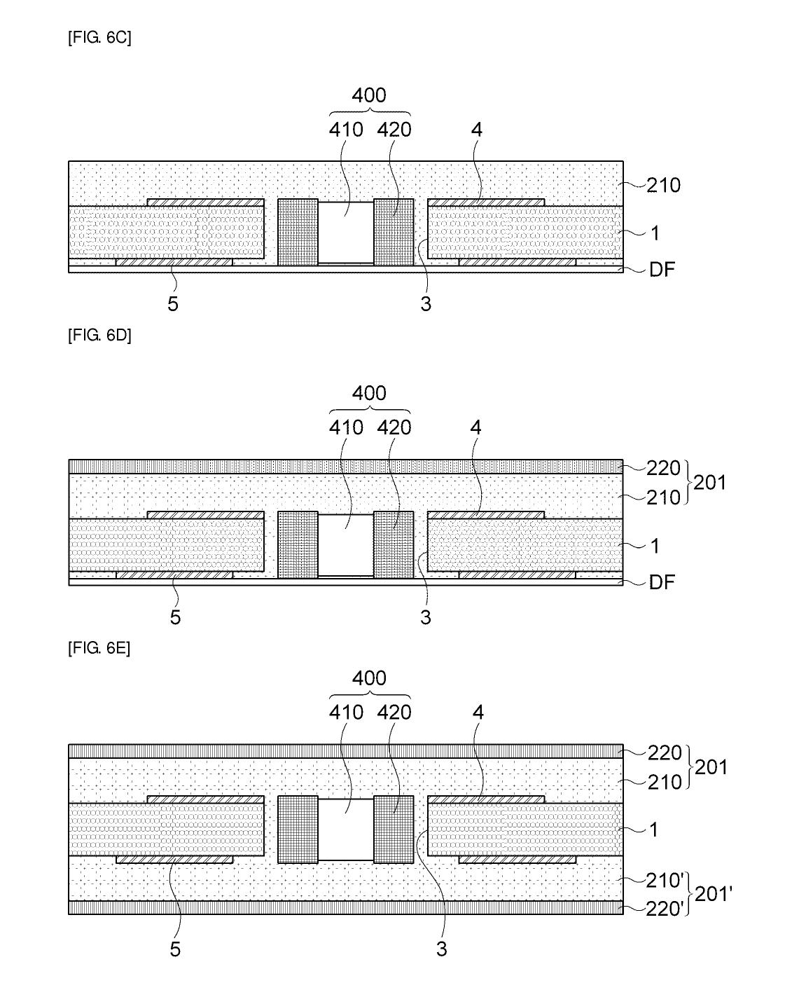

FIG. 5 is a view schematically showing a circuit board 2000 in accordance with another embodiment of the present invention.

Referring to FIG. 5, a circuit board 2000 in accordance with another embodiment of the present invention may include an electronic component 400, a first insulating layer 1, a second insulating layer 201, a conductor pattern 313, and a via 100.

As shown, it will be understood that the electronic component 400 having an external electrode 420 formed in a body portion 410 is embedded in the circuit board 2000 in accordance with the present embodiment and the via 100 is connected to the external electrode 420 to be connected to the conductor pattern.

Therefore, hereinafter, descriptions overlapping with those described above will be omitted.

Referring to FIG. 5, the electronic component 400 may be a passive device such as a capacitor or an inductor or an active device such as IC, and the external electrode 420 (or external terminal) for being connected to the outside may be provided in a portion of the body portion 410.

The first insulating layer 1 may have a cavity 3 for receiving the electronic component 400, and an inner layer pattern 4 and 5 may be provided on one or both of an upper surface and a lower surface of the first insulating layer 1. In the drawing, the inner layer pattern formed on the upper surface of the first insulating layer 1 is referred to as the upper inner layer pattern 4, and the inner layer pattern formed on the lower surface of the first insulating layer 1 is referred to as the lower inner layer pattern 5.

Meanwhile, the first insulating layer 1 may be a core substrate or a metal core including a metal material.

The second insulating layer 201 may be provided on or under the first insulating layer 1 and include the above-described first insulating portion 210 and second insulating portion 220. The conductor patterns 311, 312, 313, and 313′ may be provided on the second insulating layer 201

At this time, the via 100 may be provided between the external electrode 420 of the electronic component 400 and the conductor pattern through the second insulating layer 201 to electrically connect the external electrode 420 and the conductor pattern 313 through a shortest path.

As described above, the via 100 may be a via formed by integrally connecting a first body 110 and a second body 120 and substantially have a shovel or spade shape.

Meanwhile, at least one conductor pattern 313 formed on the second insulating layer 201 may be connected to the external electrode 420 through the via 100, and another conductor pattern may be connected to the inner layer pattern 4 through the via 100′ or form wiring without being connected to the via 100 and 100′.

Accordingly, it is possible to maintain signal transmission capability at a level similar to the prior art or improve the signal transmission capability while reducing a line width or a pattern pitch of the conductor pattern 313 connected to the electronic component 400.

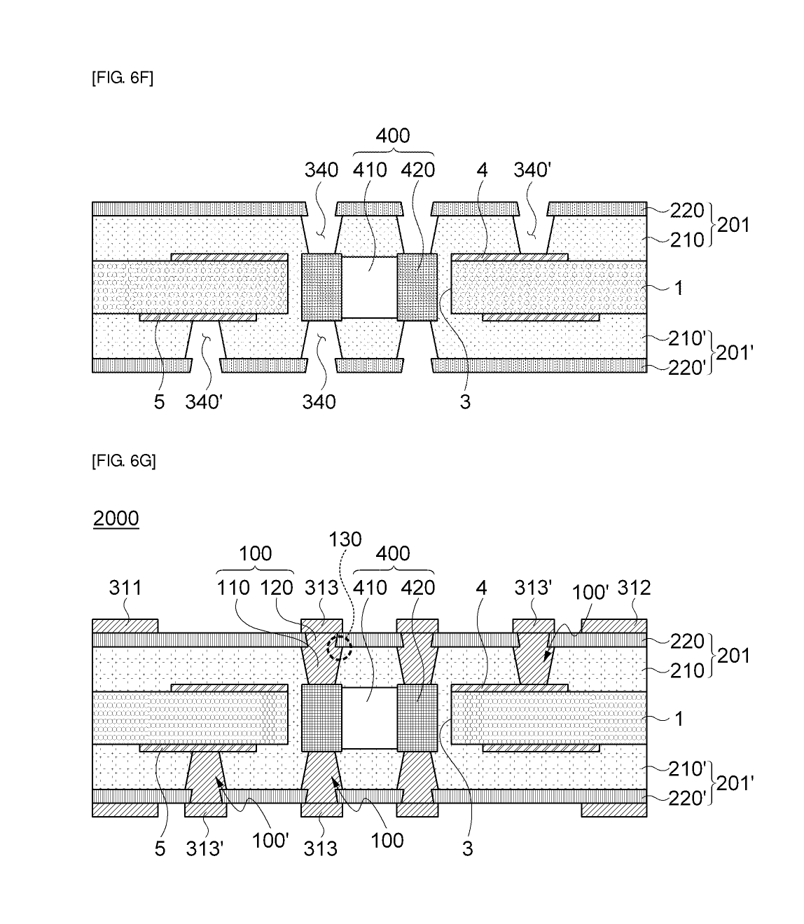

FIGS. 6a to 6g are process cross-sectional views schematically showing a method of manufacturing a circuit board 2000 in accordance with another embodiment of the present invention.

FIG. 6a schematically shows the state in which a first insulating layer 1 having a cavity 3 is provided, and FIG. 6b schematically shows the state in which an electronic component 400 is inserted in the cavity 3.

At this time, when the cavity 3 is formed to pass through the first insulating layer 1, a detach film (DF) for temporarily mounting the electronic component 400 may be attached to one surface of the first insulating layer 1 to fix the electronic component 400 in the cavity 3.

Meanwhile, although not shown, it is apparent that the cavity can be implemented to form a recess in the direction from an upper surface to a lower surface without passing through the first insulating layer.

In this case, the electronic component 400 may be disposed inside the recess without a separate DF. The electronic component 400 may be fixed after applying an adhesive on a bottom of the recess or on a bottom thereof when necessary.

Next, referring to FIGS. 6c and 6d, after forming a first insulating portion 210 on the first insulating layer 1, a second insulating portion 220 is formed on the first insulating portion 210.

At this time, the first insulating portion 210 and the second insulating portion 220 may be defined as a second insulating layer 201. Some of the material of the first insulating portion 210 may be introduced into the region between the cavity 3 and the electronic component 400 to fix the electronic component 400.

Next, referring to FIG. 6e, the DF under the first insulating layer 1 is removed, and another second insulating layer 201′ is further provided. Accordingly, the electronic component 400 can be completely embedded in the circuit board, and when an external electrode 420 is provided also on a lower surface of the electronic component 400, it is possible to connect wiring in the upper and lower directions of the electronic component 400.

Next, referring to FIG. 6f, via holes 340 and 340′ are formed to expose the external electrode 420 of the electronic component 400 or an inner layer pattern 4 of the first insulating layer 1.

At this time, since the second insulating layer 201 includes the first insulating portion 210 and the second insulating portion 220, the via holes 340 and 340′ can be formed to substantially have a shovel or spade shape as shown.

Next, referring to FIG. 6g, a via 100 is formed in the via hole and conductor patterns 311, 312, 313, and 313′ are formed to manufacture a circuit board 2000.

At this time, although not shown, it is apparent that the insulating layer and the conductor pattern can be further formed outside the second insulating layer 201.

The circuit board in accordance with an embodiment of the present invention configured as above can miniaturize the conductor pattern etc. formed around the via by remarkably reducing the area of the upper surface of the via than the prior art while maintaining the area of the lower surface of the via at a level similar to the prior art.

Further, it is possible to improve current pass characteristics by increasing the volume of the via compared to the area of the upper surface of the via.

What is claimed is:

1. A circuit board comprising:
an insulating layer;
an upper conductor pattern and a lower conductor pattern respectively provided on an upper surface and a lower surface of the insulating layer; and
a via passing through the insulating layer to be in contact with the upper conductor pattern and the lower conductor pattern and having a bent portion whose cross-sectional area or diameter changes discontinuously.

2. The circuit board according to claim 1, wherein the via comprises:
a first body in contact with the lower conductor pattern; and
a second body in contact with the upper conductor pattern and having a smaller volume than the first body, wherein the first body and the second body are formed integrally.

3. The circuit board according to claim 2, wherein the bent portion is formed on the boundary between the first body and the second body.

4. The circuit board according to claim 2, wherein the insulating layer comprises:
a first insulating portion in which the first body is formed; and
a second insulating portion which is formed on the first insulating portion and in which the second body is formed.

5. The circuit board according to claim 4, wherein the thickness of the second insulating portion is less than 0.9 times the thickness of the first insulating portion.

6. The circuit board according to claim 4, wherein the second insulating portion has a lower laser absorption rate than the first insulating portion.

7. The circuit board according to claim 4, wherein the second insulating portion has a higher chemical resistance to a desmear process solution than the first insulating portion.

8. The circuit board according to claim 7, wherein the desmear process solution comprises a sodium hydroxide solution or a permanganate solution.

9. The circuit board according to claim 4, wherein the first insulating portion comprises PPG or ABF, and
the second insulating portion comprises at least one material selected from the group consisting of bisphenol A, phenolic novolac resin, silica, and TiO₄.

10. The circuit board according to claim 2, wherein a minimum value of the cross-sectional diameter of the second body is smaller than the diameter of an upper surface of the via and larger than the diameter of a lower surface of the via.

11. The circuit board according to claim 2, wherein the diameter or cross-sectional area of the first body and the second body increases from the lower conductor pattern side to the upper conductor pattern side.

12. The circuit board according to claim 11, wherein an acute angle between a lower surface of the first insulating portion and a side surface of the first body is larger than that between a lower surface of the second insulating portion and a side surface of the second body.

13. The circuit board according to claim 11, wherein the diameter or cross-sectional area of the via is maximum in the bent portion.

14. A circuit board comprising:
a first insulating layer having a cavity;
an electronic component at least partially inserted in the cavity and having an external electrode;
a second insulating layer provided on the first insulating layer to cover the electronic component;
a conductor pattern provided on an upper surface of the second insulating layer; and
a via passing through the second insulating layer to be in contact with the conductor pattern and the external electrode and having a bent portion whose cross-sectional area or diameter changes discontinuously.

15. The circuit board according to claim 14, wherein the via comprises:
a first body in contact with the external electrode; and
a second body in contact with the conductor pattern and having a smaller volume than the first body, wherein the first body and the second body are formed integrally.

16. The circuit board according to claim 15, wherein the bent portion is formed on the boundary between the first body and the second body.

17. The circuit board according to claim 16, wherein the diameter or cross-sectional area of the via is maximum in the bent portion.

18. The circuit board according to claim 15, wherein the second insulating layer comprises:
a first insulating portion in which the first body is formed; and
a second insulating portion which is formed on the first insulating portion and in which the second body is formed.

19. The circuit board according to claim 18, wherein the thickness of the second insulating portion is less than 0.9 times the thickness of the first insulating portion.

20. The circuit board according to claim 18, wherein the second insulating portion has a lower laser absorption rate and a higher chemical resistance to a desmear process solution than the first insulating portion.

21. The circuit board according to claim 14, wherein the second insulating layers are formed on an upper surface and a lower surface of the first insulating layer, and the conductor patterns are formed on and under the first insulating layer in plural number.

22. The circuit board according to claim 21, wherein the external electrodes are formed on an upper surface and a lower surface of the electronic component in plural number, and the vias are formed on and under the electronic component in plural number to be in contact with the conductor pattern and the external electrode, respectively.

23. A method of manufacturing a circuit board, comprising:
forming a via hole in an insulating layer having a lower conductor pattern on a lower surface to expose the lower conductor pattern;
forming a via by providing a conductive material in the via hole; and
forming an upper conductor pattern in contact with an upper surface of the via, wherein the via is formed to have a bent portion whose cross-sectional area or diameter changes discontinuously.

24. The method of manufacturing a circuit board according to claim 23, wherein the insulating layer comprises a first insulating portion in contact with the lower conductor pattern and a second insulating portion in contact with the upper conductor pattern, and
the thickness of the second insulating portion is less than 0.9 times the thickness of the first insulating portion.

25. The method of manufacturing a circuit board according to claim 23, wherein the insulating layer comprises a first insulating portion in contact with the lower conductor pattern and a second insulating portion in contact with the upper conductor pattern,
forming the via hole comprises a process of irradiating laser to the lower conductor pattern from above the second insulating portion, and
the second insulating portion has a lower laser absorption rate than the first insulating portion.

26. The method of manufacturing a circuit board according to claim 23, wherein the insulating layer comprises a first insulating portion in contact with the lower conductor pattern and a second insulating portion in contact with the upper conductor pattern,
forming the via hole comprises a process of irradiating laser to the lower conductor pattern from above the second insulating portion and a process of removing a portion of the second insulating portion and a portion of the first insulating portion using a desmear process solution, and
the second insulating portion has a higher chemical resistance to the desmear process solution than the first insulating portion.

27. The method of manufacturing a circuit board according to claim 26, wherein the first insulating portion comprises PPG or ABF, and
the second insulating portion comprises at least one material selected from the group consisting of bisphenol A, phenolic novolac resin, silica, and TiO₄.

28. A method of manufacturing a circuit board, comprising:
inserting at least a portion of an electronic component having an external electrode in a cavity provided in a first insulating layer;
forming a second insulating layer on the first insulating layer to cover the electronic component;
forming a via hole through the second insulating layer to expose the external electrode;
forming a via by providing a conductive material in the via hole; and
forming a conductor pattern in contact with an upper surface of the via, wherein the via is formed to have a bent portion whose cross-sectional area or diameter changes discontinuously.

29. The method of manufacturing a circuit board according to claim 28, wherein the second insulating layer comprises a first insulating portion in contact with the external electrode and a second insulating portion in contact with the conductor pattern, and
the second insulating portion has a lower laser absorption rate and a higher chemical resistance to a desmear process solution than the first insulating portion.

30. The method of manufacturing a circuit board according to claim 29, wherein an inner layer pattern is further provided on a surface of the first insulating layer,
the first insulating portion also covers the inner layer pattern, and
in forming the via hole, a via hole is further formed to expose the inner layer pattern by passing through the second insulating portion and the first insulating portion.
